(19) United States
(12) Patent Application Publication
(10) Pub. No.: US 2014/0352928 A1
(43) Pub. Date: Dec. 4, 2014

(54) Electronic Device, and Heat Dissipation System and Heat Dissipation Method of Electronic Device

(71) Applicant: Huawei Technologies Co., Ltd., Shenzhen (CN)

(72) Inventors: Shuliang Huang, Shenzhen (CN); Zhaoxia Luo, Shenzhen (CN); Youhe Ke, Shenzhen (CN)

(21) Appl. No.: 14/462,810

(22) Filed: Aug. 19, 2014

Related U.S. Application Data
(63) Continuation of application No. PCT/CN2012/085944, filed on Dec. 5, 2012.

(30) Foreign Application Priority Data
Mar. 21, 2012 (CN) 201210076472.6

(51) Int. Cl. H05K 7/20

(52) U.S. Cl. CPC H05K 7/20236
USPC 165/104.31

(57) ABSTRACT

An electronic device and a heat dissipation system and heat dissipation method are provided that can be used in combination with a common heat exchange/refrigerating electronic device, thereby reducing an investment cost. The heat dissipation system of an electronic device includes a cooling pool, a heat exchanger, and at least one circulating pump, where a cooling medium is provided in the cooling pool, and the electronic device and the heat exchanger are immersed in the cooling medium; the circulating pump is configured to drive the cooling medium to circulatively flow between the electronic device and the heat exchanger; and a heat exchange medium is provided in the heat exchanger and used to exchange heat with the cooling medium, and the heat exchange medium flows out of the heat exchanger for cooling and then flows back, so as to discharge heat released by the electronic device.

### CROSS-REFERENCE TO RELATED APPLICATIONS

This application is a continuation of International Application No. PCT/CN2012/085944, filed on Dec. 5, 2012, which claims priority to Chinese Patent Application No. 201210076472.6, filed on Mar. 21, 2012, both of which are hereby incorporated by reference in their entireties.

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

The present disclosure relates to the field of heat dissipation technologies, and in particular, to an electronic device and a heat dissipation system and heat dissipation method of an electronic device.

### BACKGROUND

Currently, heat dissipation is generally performed for an electronic device, such as a blade server, in an air-cooled or liquid-cooled manner. In an existing liquid-cooled heat dissipation system, an electronic device, such as a blade server, is generally immersed in a cooling medium, and the cooling medium is brought, by circulation, out of a cabinet for cooling and flowing back, so as to dissipate heat for the electronic device in the cabinet.

In the foregoing process, the inventor finds that the prior art has at least the following problem:

A cooling medium is an insulating heat conducting liquid. However, currently, pure water or another working medium is generally used for a common refrigerating water machine or another cooling apparatus, and the cooling medium is not supported. A heat exchange/refrigerating device supporting the cooling medium needs to be separately customized or purchased, thereby causing an additional investment cost.

### SUMMARY

A technical issue that the present disclosure needs to address is to provide an electronic device and a heat dissipation system and heat dissipation method of an electronic device, which can be used in combination with a common heat exchange/refrigerating device, without a need of separate customization or purchase, thereby reducing an investment cost.

To achieve the foregoing objective, the following technical solutions are used in embodiments of the present disclosure:

A heat dissipation system of an electronic device includes a cooling pool, a heat exchanger, and at least one circulating pump, where: a cooling medium is provided in the cooling pool, and the electronic device and the heat exchanger are immersed in the cooling medium; the circulating pump is configured to drive the cooling medium to circulatively flow between the electronic device and the heat exchanger; and a heat exchange medium is provided in the heat exchanger and used to exchange heat with the cooling medium, and the heat exchange medium flows out of the heat exchanger for cooling and then flows back.

An embodiment of the present disclosure further provides an electronic device, which is disposed with a heat dissipation system provided in an embodiment of the present disclosure.

An embodiment of the present disclosure further provides a heat dissipation method of an electronic device, including: immersing the electronic device and a heat exchanger in a cooling medium; driving the cooling medium to circulatively flow between the electronic device and the heat exchanger; and draining a heat exchange medium in the heat exchanger out of the heat exchanger for cooling and flowing back.

According to the electronic device and the heat dissipation system and heat dissipation method of an electronic device provided in the embodiments of the present disclosure, a cooling medium circulatively flows between an electronic device and a heat exchanger, heat released by the electronic device is transferred to a heat exchange medium in the heat exchanger by flowing of the cooling medium, and after absorbing the heat, the heat exchange medium flows out for cooling and then flows back, so as to discharge the heat released by the electronic device. A common heat exchange/refrigerating device, such as a refrigerating water machine, may be used when the heat exchange medium undergoes cooling outside, without a need of separately customizing or purchasing a heat exchange/refrigerating device supporting the cooling medium, thereby reducing an investment cost.

### BRIEF DESCRIPTION OF THE DRAWINGS

To describe the technical solutions in the embodiments of the present disclosure more clearly, the following briefly introduces the accompanying drawings required for describing the embodiments. The accompanying drawings in the following description show merely some embodiments of the present disclosure, and a person of ordinary skill in the art may still derive other drawings from these accompanying drawings without creative efforts.

FIG. 1 is a first schematic structural diagram of a heat dissipation system according to an Embodiment 1 of the present disclosure;

FIG. 2 is a schematic structural diagram of a liquid-to-liquid heat exchanger according to an Embodiment 1 of the present disclosure;

FIG. 3 is a second schematic structural diagram of a heat dissipation system according to an Embodiment 1 of the present disclosure;

FIG. 4 is a third schematic structural diagram of a heat dissipation system according to an Embodiment 1 of the present disclosure; and

FIG. 5 is a flowchart of a heat dissipation method according to an Embodiment 2 of the present disclosure.

Reference numeral in the accompanying drawings are described as follows:

11—Cooling pool, 12—Heat exchanger, 13—Circulating pump, 14—Electronic device, 15—Spacer plate, 16—Cooling apparatus, 111—Cooling medium, 121—Heat sink, and 122—Pipe interface.

### DETAILED DESCRIPTION

The following clearly describes the technical solutions in the embodiments of the present disclosure with reference to the accompanying drawings in the embodiments of the present disclosure. The described embodiments are merely a part rather than all of the embodiments of the present disclosure. All other embodiments obtained by a person of ordinary skill in the art based on the embodiments of the present disclosure without creative efforts shall fall within the protection scope of the present disclosure.

The embodiments of the present disclosure provide an electronic device and a heat dissipation system and heat dissipation method of an electronic device, which can be used in combination with a common heat exchange/refrigerating device, without a need of separate customization or purchase, thereby reducing an investment cost.

The electronic device provided in the embodiments of the present disclosure may be a blade server or the like, which is not limited in the embodiments of the present disclosure.

### Embodiment 1

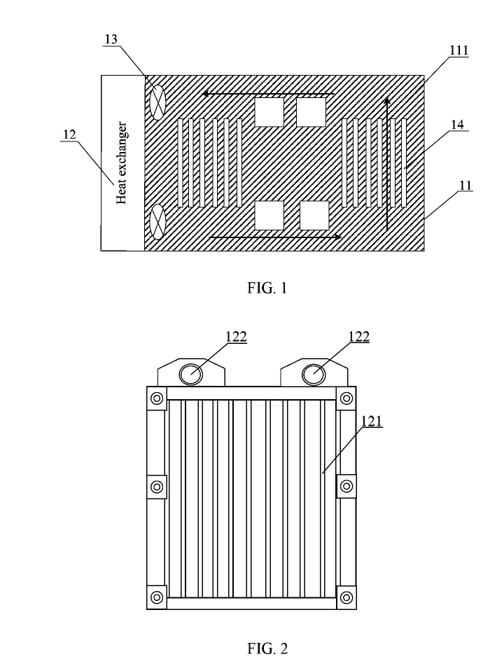

As shown in FIG. 1, an embodiment of the present disclosure provides a heat dissipation system of an electronic device, including a cooling pool 11, a heat exchanger 12, and at least one circulating pump 13, where: a cooling medium 111 is provided in the cooling pool 11, and an electronic device 14 and the heat exchanger 12 are immersed in the cooling medium 111; the circulating pump 13 is configured to drive the cooling medium 111 to circulatively flow between the electronic device 14 and the heat exchanger 12, where a direction indicated by an arrow in FIG. 1 is a direction in which the cooling medium 111 flows in the cooling pool 11; and a heat exchange medium is provided in the heat exchanger 13 and used to exchange heat with the cooling medium 111, and the heat exchange medium flows out of the heat exchanger 13 for cooling and then flows back, so as to discharge heat released by the electronic device 14.

In this embodiment, the electronic device 14 is immersed in the cooling medium 111, which may be understood as that components forming the electronic device 14 are immersed in the cooling medium 111. Optionally, a cabinet used to hold the electronic device 14 is filled with the cooling medium 111, thereby forming the cooling pool 11, and the components of the electronic device 14 and the heat exchanger 12 are immersed in the cooling medium 111.

As shown in FIG. 1, the heat exchanger 12 is disposed on a left side of the cooling pool 11, the cooling medium 111 performs heat exchange in the area, and transfers heat released by the electronic device 14 to the heat exchange medium in the heat exchanger 12 by flowing of the cooling medium 111, and the heat exchange medium brings the heat out, so as to discharge the heat.

In this embodiment, the cooling medium 111 is an insulating heat conducting liquid, the cooling medium 111 circulatively flows between the electronic device 14 and the heat exchanger 12, and transfers the heat released by the electronic device 14 to the heat exchange medium in the heat exchanger 12 by the flowing of the cooling medium 111, and after absorbing the heat, the heat exchange medium flows out of the cooling pool 11 for cooling and then flows back. A common heat exchange/refrigerating device, such as a refrigerating water machine, may be used when the heat exchange medium undergoes cooling outside, without a need of separately customizing or purchasing a heat exchange/refrigerating device supporting the cooling medium, thereby reducing an investment cost.

In this embodiment, natural convection is not used for the cooling medium 111; instead, the circulating pump 13 is used to drive the cooling medium 111 to circulatively flow in the cooling pool 11 and transfer the heat released by the electronic device 14 to the heat exchange medium in the heat exchanger 12. Therefore, in this embodiment, a position of the heat exchanger 12 can be flexibly arranged and is not limited to an upper side of the electronic device 14, thereby saving height space and reducing a requirement for a height limit on the components of the electronic device 14. Optionally, the heat exchanger 12 is disposed on one side of the cooling pool 11. As shown in FIG. 1, the heat exchanger 12 is disposed on the left side of the cooling pool 11. In this embodiment, a position and a quantity of the circulating pump 13 may also be adjusted according to an actual requirement.

In this embodiment, other than the position of the heat exchanger 12, positions of the components of the electronic device 14 can also be flexibly arranged. Therefore, according to the heat dissipation system provided in this embodiment, structural optimization design can be performed, according to a specific condition, on an entire device including the electronic device and the heat dissipation system, so as to save space and reduce a floor area of the device. In addition, in this embodiment, the circulating pump 13 provides a driving force for the cooling medium 111 to flow in a direction, and flowing of the cooling medium improves heat dissipation efficiency of the components of the electronic device 14.

Optionally, in this embodiment, the heat exchanger is a liquid-to-liquid heat exchanger.

A specific structure of a liquid-to-liquid heat exchanger varies. FIG. 2 shows a specific structure of a liquid-to-liquid heat exchanger. The liquid-to-liquid heat exchanger includes several heat sinks 121, and a passing channel for the heat exchange medium is provided in each heat sink. A pipe interface 122 is further provided in the liquid-to-liquid heat exchanger for the heat exchange medium to pass through, and includes a liquid inlet and a liquid outlet. The heat exchange medium flows out of the heat exchanger from the liquid outlet, undergoes cooling, and then flows back into the heat exchanger from the liquid inlet. The heat released by the electronic device is transferred to the heat exchanger by the flowing of the cooling medium. When the cooling medium flows through a gap between the heat sinks 121, the cooling medium exchanges heat with the heat exchange medium in the heat exchanger, and the heat exchange medium brings the heat out.

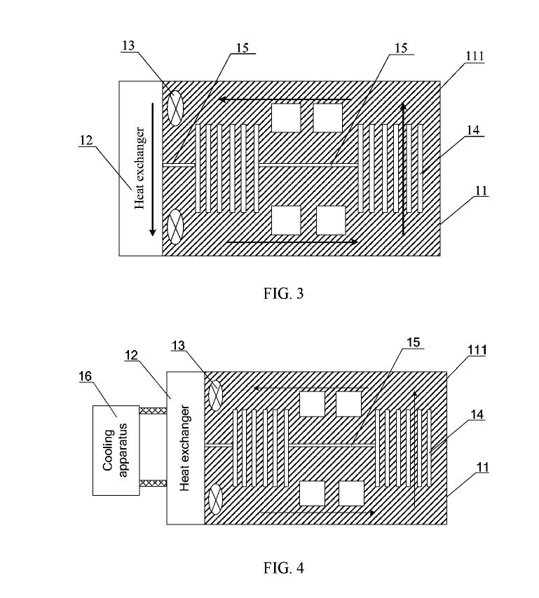

Optionally, as shown in FIG. 3, the heat dissipation system provided in this embodiment may further include a spacer plate 15 which is used to divide the cooling pool 11 into two runners. As indicated by an arrow in FIG. 3, the cooling medium 111 flows from the electronic device 14 to the heat exchanger 12 in one of the runners, and flows from the heat exchanger 12 to the electronic device 14 in the other runner. The cooling pool is divided into two runners by using the spacer plate, thereby preventing a low temperature cooling medium that flows out of the heat exchanger from mixing with a high temperature cooling medium that is to flow into the heat exchanger, so that the heat flows with the cooling medium in order and the cooling medium transfers the heat released by the electronic device to the heat exchange medium, thus improving heat dissipation efficiency.

Further, as shown in FIG. 4, the heat dissipation system further includes a cooling apparatus 16 disposed outside the cooling pool 11, where the heat exchanger 12 is connected to the cooling apparatus 16 by using a pipe, and the heat exchange medium in the heat exchanger 12 flows out of the heat exchanger 12, undergoes cooling by the cooling apparatus 16, and then flows back. Optionally, the cooling apparatus 16 may also be replaced with a refrigerating water machine, and the heat exchange medium is water. The heat exchanger is connected to a common cooling apparatus or refrigerating water machine, without a need of separately customizing or purchasing a heat exchange/refrigerating device, thereby reducing an investment cost.

The heat dissipation system provided in the embodiment of the present disclosure can be used in combination with a common heat exchange/refrigerating device, without a need of separate customization or purchase, thereby reducing an investment cost. A circulating pump is used to drive a cooling medium to circulatively flow in a cooling pool, so as to help improve heat dissipation efficiency. In addition, a position of a heat exchanger and a position of an electronic device can be flexibly arranged in the cooling pool, so as to save space and reduce a floor area.

An embodiment of the present disclosure further provides an electronic device which is disposed with any one heat dissipation system provided in the embodiments of the present disclosure.

A liquid cooled heat dissipation system is adopted by the electronic device provided in the embodiment of the present disclosure. The heat dissipation system provides high heat dissipation efficiency and can be used in combination with a common heat exchange/refrigerating device, thereby reducing an investment cost.

### Embodiment 2

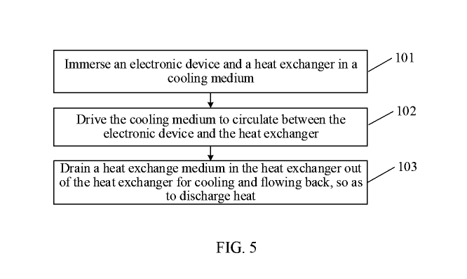

An embodiment of the present disclosure provides a heat dissipation method of an electronic device, as shown in FIG. 5, including:

Step 101: Immerse the electronic device and a heat exchanger in a cooling medium, where a heat exchange medium is provided in the heat exchanger, so as to exchange heat with the cooling medium.

Step 102: Drive the cooling medium to circulatively flow between the electronic device and the heat exchanger. Optionally, use a circulating pump to drive the cooling medium to flow, where a position and a quantity of the circulating pump may be adjusted according to a requirement.

Step 103: Drain the heat exchange medium in the heat exchanger out of the heat exchanger for cooling and flowing back, so as to discharge heat released by the electronic device.

The heat dissipation method provided in the embodiment of the present disclosure can be used in combination with a common heat exchange/refrigerating device, thereby reducing an investment cost. A cooling medium is driven to circulatively flow in a cooling pool, so as to help improve heat dissipation efficiency. In addition, a position of a heat exchanger and a position of an electronic device can be flexibly arranged in the cooling pool, thereby achieving objectives of optimizing structural design, saving space, and reducing a floor area.

Optionally, the heat exchanger is a liquid-to-liquid heat exchanger.

Optionally, the heat exchanger is disposed on one side of the cooling pool.

Further, step 103 of the heat dissipation method provided in the embodiment of the present disclosure is specifically: drain the heat exchange medium out of the heat exchanger for cooling by a cooling apparatus or a refrigerating water machine and flowing back, where the cooling apparatus or the refrigerating water machine is disposed outside the cooling pool and connected to the heat exchanger by using a pipe.

The heat dissipation method provided in the embodiment of the present disclosure can be used with a common heat exchange/refrigerating device, thereby reducing an investment cost. According to the heat dissipation method provided in this embodiment, heat dissipation efficiency is high, and a position of a heat exchanger and a position of an electronic device can be flexibly arranged in a cooling pool, thereby achieving objectives of optimizing structural design, saving space, and reducing a floor area.

The foregoing descriptions are merely specific implementation manners of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A heat dissipation system of an electronic device, comprising:
a cooling pool;
a heat exchanger; and
at least one circulating pump,
wherein a cooling medium is provided in the cooling pool, and the electronic device and the heat exchanger are immersed in the cooling medium,
wherein the circulating pump is configured to drive the cooling medium to circulatively flow between the electronic device and the heat exchanger, and
wherein a heat exchange medium is provided in the heat exchanger and used to exchange heat with the cooling medium, and the heat exchange medium flows out of the heat exchanger for cooling and then flows back.

2. The heat dissipation system according to claim 1, wherein the heat exchanger is a liquid-to-liquid heat exchanger.

3. The heat dissipation system according to claim 1, further comprising a spacer plate configured to divide the cooling pool into two runners, wherein the cooling medium flows from the electronic device to the heat exchanger in one of the runners, and flows from the heat exchanger to the electronic device in the other runner.

4. The heat dissipation system according to claim 1, wherein the heat exchanger is disposed on one side of the cooling pool.

5. The heat dissipation system according to claim 1, further comprising a cooling apparatus or a refrigerating water machine disposed outside the cooling pool, wherein the heat exchanger is connected to the cooling apparatus or the refrigerating water machine by using a pipe, and the heat exchange medium in the heat exchanger flows out of the heat exchanger, undergoes cooling by the cooling apparatus or the refrigerating water machine, and then flows back.

6. An apparatus, comprising:
an electronic device; and
a heat dissipation system disposed with the electronic device,
wherein the heat dissipation system comprises a cooling pool, a heat exchanger, and at least one circulating pump,
wherein a cooling medium is provided in the cooling pool, and the electronic device and the heat exchanger are immersed in the cooling medium,
wherein the circulating pump is configured to drive the cooling medium to circulatively flow between the electronic device and the heat exchanger, and
wherein a heat exchange medium is provided in the heat exchanger and used to exchange heat with the cooling medium, and the heat exchange medium flows out of the heat exchanger for cooling and then flows back.

7. The apparatus according to claim 6, wherein the heat exchanger is a liquid-to-liquid heat exchanger.

8. The apparatus according to claim 6, wherein the heat dissipation system further comprises a spacer plate configured to divide the cooling pool into two runners, wherein the cooling medium flows from the electronic device to the heat exchanger in one of the runners, and flows from the heat exchanger to the electronic device in the other runner.

9. The apparatus according to claim 6, wherein the heat exchanger is disposed on one side of the cooling pool.

10. The apparatus according to claim 6, wherein the heat dissipation system further comprises a cooling apparatus or a refrigerating water machine disposed outside the cooling pool, wherein the heat exchanger is connected to the cooling apparatus or the refrigerating water machine by using a pipe, and the heat exchange medium in the heat exchanger flows out of the heat exchanger, undergoes cooling by the cooling apparatus or the refrigerating water machine, and then flows back.

11. A heat dissipation method of an electronic device, comprising:
immersing the electronic device and a heat exchanger in a cooling medium;
driving the cooling medium to circulatively flow between the electronic device and the heat exchanger; and
draining a heat exchange medium in the heat exchanger out of the heat exchanger for cooling and flowing back.

12. The method according to claim 11, wherein the heat exchanger is a liquid-to-liquid heat exchanger.

13. The method according to claim 11, wherein the heat exchanger is disposed on one side of a cooling pool.

14. The method according to claim 11, wherein that the heat exchange medium in the heat exchanger flows out of the heat exchanger for cooling and then flows back comprises draining the heat exchange medium out of the heat exchanger for cooling by a cooling apparatus or a refrigerating water machine and flowing back, wherein the cooling apparatus or the refrigerating water machine is disposed outside the cooling pool and connected to the heat exchanger by using a pipe.
